(19) United States
(12) Patent Application Publication
(10) Pub. No.: US 2004/0183195 A1
(43) Pub. Date: Sep. 23, 2004

(54) [UNDER BUMP METALLURGY LAYER]

(76) Inventors: Min-Lung Huang, Kaohsiung (TW); Chi-Long Tsai, Taitung (TW); Chao-Fu Weng, Tainan (TW); Ching-Huei Su, Kaohsiung (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/708,664

(22) Filed: Mar. 18, 2004

(30) Foreign Application Priority Data
Mar. 20, 2003 (TW) 92106131

(51) Int. Cl. H01L 23/48

(52) U.S. Cl. 257/737

(57) ABSTRACT

The present invention relates to an under bump metallurgy layer, comprising an adhesion layer, a barrier layer and a wetting-barrier layer. The adhesion layer, the barrier layer and the wetting-barrier layer are arranged sequentially on the pad of the chip, and the wetting-barrier layer is disposed between the barrier layer and the bump. The wetting-barrier layer, containing nickel, can improve the bonding ability between the pad and the bump. Also, the invention relates to a flip chip structure including at least a chip, a plurality of bumps and the under bump metallurgy mentioned above.

### CROSS REFERENCE TO RELATED APPLICATIONS

This application claims the priority benefit of Taiwan application serial no. 92106131, filed Mar. 20, 2004.

### BACKGROUND OF INVENTION

1. Field of Invention

The present invention relates to an under bump metallurgy layer and a flip chip structure with the under bump metallurgy layer. More particularly, the present invention relates to an under bump metallurgy layer providing excellent attachment between the bonding pad of the chip and the bump, and the flip chip structure adopting the aforementioned under bump metallurgy layer.

2. Description of Related Art

At present, the market of multimedia applications rapidly expands. The integrated circuit (IC) packaging needs to be improved following the developing trends of electronic devices such as digitalization, network localization, and user friendliness. In order to meet the above requirements, electronic devices must have multiple functions and high integration and maintain high operating speed, miniaturization, lightweight, and low cost. High-density packages, such as ball grid arrays (BGAs), chip scale packages (CSPs), flip chips (F/C), and multi-chip modules (MCMs) have been developed.

The flip chip interconnect technology used in the flip chips can be summarized as follows. A plurality of pads are arranged on the active surface of the chip (die) in arrays and bumps are formed on the pads with the under bump metallurgy layer therebetween. The chip is face-down bonded (flipped) to contacts of the substrate or the printed circuit board (PCB) via bumps. Since the flip chip technology has the advantages of achieving the high density of minimizing the package region and shortening the signal transmission path, the flip chip technology has been widely applied to high pin count chip packages.

FIG. 1 is a cross-sectional view of a prior flip chip structure. Referring to FIG. 1, the clip chip 100 includes a chip 110, an under bump metallurgy (UBM) layer 120 and a plurality of bumps 130 (with only one bump shown). The chip 110 has an active surface 112, a passivation layer 114 and a plurality of bonding pads 116 (with only one pad shown) on the active surface. The UBM layer 120 is arranged between the bump 130 and the bonding pad 116 and between the bump 130 and the passivation layer 114, as an interface for connection.

Due to the soldering characteristics of tin (Sn) or tin-lead alloy, tin or tin-lead alloy is usually used as a solder material for the bumps 130. In order to reduce pollution to the environments, lead free solder has been developed. However, the solder materials used still include tin, regardless lead containing or lead free solder materials.

The UBM layer 120 includes an adhesion layer 122, a barrier layer 124, and a wetting (solder) layer 126. The adhesion layer 122 can improve adhesion between the bonding pad 116 and the barrier layer 124. The barrier layer 124 can act as a barrier against diffusion reaction of bumps 130. The wetting layer 126 can increase the attachment of the UBM layer 120 to the bumps 130.

It is noted that metal in the wetting layer 126 of the UBM layer 120 will react with tin in the bumps 130 to form SnCu inter-metallic compounds (IMC), if the wetting layer 126 is a copper layer. Moreover, tin may further diffuse into the barrier layer 124 and reacts with Ni—V alloy to form SnNi inter-metallic compounds, which are in the form of incontinuos clots. If the adhesion layer is made of aluminum, because the adhesion between the SnNi inter-metallic compounds and the Al layer is poor, the bumps are easily peeled from the interface.

### SUMMARY OF INVENTION

Accordingly, the present invention provides an under bump metallurgy (UBM) layer, which can decrease the formation rate of the inter-metallic compounds.

The present invention provides a flip chip structure, which has excellent adhesion between the bonding pads and the bumps.

As embodied and broadly described herein, the invention provides an under bump metallurgy (UBM) layer, which can improves adhesion between the bonding pads and the bumps, especially for the tin-containing bumps. The UBM layer includes an adhesion layer, a barrier layer, and a wetting-barrier layer. The adhesion layer is disposed on the bonding pads, while the barrier layer is disposed on the adhesion layer. The wetting-barrier layer is arranged between the barrier layer and the bumps, and the materials for forming the wetting-barrier layer include nickel metal, for example.

As embodied and broadly described herein, the invention provides a flip chip structure, comprising a chip, an UBM layer and at least a bump. The chip includes an active surface, a passivation layer and a plurality of bonding pads arranged on the active surface. The passivation layer exposes the bonding pads. The UBM layer includes an adhesion layer, a barrier layer, and a wetting-barrier layer. The adhesion layer is disposed on the bonding pads, while the barrier layer is disposed on the adhesion layer. The wetting-barrier layer is arranged between the barrier layer and the bumps, and the materials for forming the wetting-barrier layer include nickel metal, for example. The bump is arranged on the wetting-barrier layer, and the materials for forming the bump include tin, for example.

As embodied and broadly described herein, the material for forming the adhesion layer of the present invention is selected from the following group consisting of titanium, titanium-tungsten alloy, chromium, titanium nitride, tantalum nitride, tantalum, aluminum and copper. If the bonding pad is made of aluminum, the material for forming the adhesion layer of the present invention is selected from the following group consisting of titanium, titanium-tungsten alloy, chromium, titanium nitride, tantalum nitride, tantalum and aluminum. If the bonding pad is made of copper, the material for forming the adhesion layer of the present invention is selected from the following group consisting of titanium, titanium-tungsten alloy, chromium, titanium nitride, tantalum nitride, tantalum, and copper. In addition, the material of the barrier layer is nickel-vanadium alloy.

As embodied and broadly described herein, an anti-oxidation layer may be arranged on the wetting-barrier layer. The anti-oxidation layer is made of gold (Au), for example.

Because the tin-containing bumps are joined with the nickel metal layer, the diffusion reaction of tin from the bumps is attenuated and the formation rate of the inter-metallic compounds is decreased. Therefore, the adhesion strength between the bumps and the bonding pads remains satisfactory for a long time and the life of the flip chip structure is extended.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional view of a prior flip chip structure.

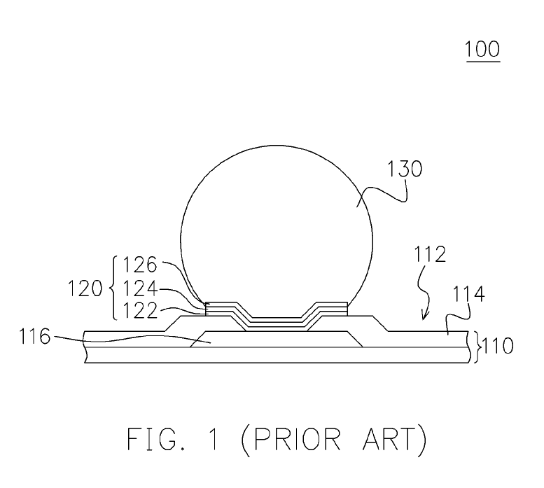

FIG. 2 is a cross-sectional view of a flip chip structure according to one preferred embodiment of the present invention.

FIG. 3 is a cross-sectional view of a flip chip structure according to another preferred embodiment of the present invention.

### DETAILED DESCRIPTION

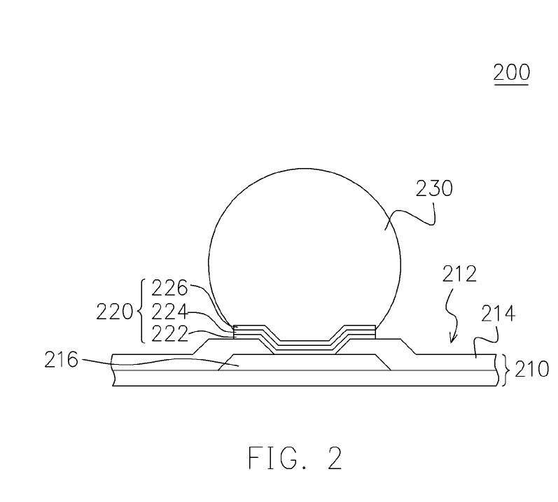

FIG. 2 is a cross-sectional view of a flip chip structure according to one preferred embodiment of the present invention. Referring to FIG. 2, the clip chip 200 includes a chip 210, an under bump metallurgy (UBM) layer 220 and a plurality of bumps 230 (with only one bump shown). The chip 210 has an active surface 212 with active devices thereon, a passivation layer 214 and a plurality of bonding pads 216 (with only one pad shown) on the active surface. The passivation layer 214 is disposed on the active surface 212 of the chip 210. For the bonding pad 216, the passivation layer 214 covers a peripheral portion of the bonding pad 216 and exposes the central portion of the bonding pad 216. The material of chip 210 can be any semiconductor materials including silicon, germanium, silicon germanium, gallium arsenide, gallium phosphide, indium arsenide, and indium phosphide. The materials for forming the passivation layer 214 can be inorganic compounds, for example, silicon oxide, silicon nitride, phosphosilicate glass (PSG). The passivation layer 214 can be a composite layer made of the aforementioned materials or mixtures thereof. The bonding pad 216 can be an aluminum pad, a copper pad or an Al—Cu alloy pad, for example. The UBM layer 220 is arranged between the bump 230 and the central portion of the bonding pad 216 and between the bump 230 and the passivation layer 214 on the bonding pad 216, as an interface for connection.

The materials of the bump 230 can be tin or tin-lead alloy, for example. Of course, the bump 230 can also be made of lead free solder, for example, tin-copper (Sn-Cu) alloy, tin-antimony (Sn—Sb) alloy, tin-bismuth (Sn—Bi) alloy, tin-indium (Sn—In) alloy, tin-zinc (Sn—Zn) alloy, tin-silver (Sn—Ag) alloy, tin-bismuth-silver alloy, tin-bismuth-antimony alloy, tin-bismuth-zinc alloy, tin-bismuth-indium alloy or tin-silver-copper alloy. It is noted that the present invention provides the UBM layer for the tin-containing bumps, for reducing the formation rate of the inter-metallic compounds.

Referring to FIG. 2, the UBM layer 220 includes an adhesion layer 222, a barrier layer 224, and a wetting-barrier (solder) layer 226. The adhesion layer 222 is disposed on the bonding pad 216, and the material for forming the adhesion layer 222 is selected from the following group consisting of titanium (Ti), titanium-tungsten (Ti—W) alloy, chromium (Cr), titanium nitride (TiN), tantalum nitride (TaN), tantalum (Ta), aluminum (Al), copper (Cu) and mixtures thereof. The adhesion layer 222 can also be a composite layer made of the aforementioned materials. If the bonding pad 216 is made of aluminum, the material for forming the adhesion layer 222 is selected from the following group consisting of titanium, titanium-tungsten alloy, chromium, titanium nitride, tantalum nitride, tantalum and aluminum. If the bonding pad 216 is made of copper, the material for forming the adhesion layer 222 is selected from the following group consisting of titanium, titanium-tungsten alloy, chromium, titanium nitride, tantalum nitride, tantalum, and copper. The adhesion layer 222 can improve adhesion between the bonding pad 216 and the barrier layer 224. The adhesion layer 222 can be formed by, for example, sputtering or electroplating/chemical plating.

The barrier layer 224 is disposed on the adhesion layer 222. The material of the barrier layer 224 is nickel-vanadium (Ni—V) alloy. The barrier layer 224 can be formed by, for example, sputtering or electroplating/chemical plating.

The wetting-barrier layer 226 is disposed between the barrier layer 224 and the bump 230, for increasing the attachment of the UBM layer 220 to the bumps 230. The wetting-barrier layer 226 contains nickel and can be formed by, for example, sputtering or electroplating/chemical plating. In order to make the attachment of UBM layer 220 to the bumps 230 more reliable, the thickness of the wetting-barrier layer may larger than the adhesion layer or the barrier layer. If the wetting-barrier layer is thick enough, it may be a wetting-barrier post. For example, a nickel post disposed on the barrier layer may be provided.

In summary, the UBM layer 220 of the present invention can be a composite layer of a Ti/Ni—V alloy/Ni layer, a Ti—W alloy/Ni—V alloy/Ni layer, a Cr/Ni—V alloy/Ni layer, a TiN/Ni—V alloy/Ni layer, a TaN/Ni—V alloy/Ni layer, a Ta/Ni—V alloy/Ni layer, a Al/Ni—V alloy/Ni layer, or a Cu/Ni—V alloy/Ni layer, for example.

It is noted that nickel atoms in the wetting-barrier layer 226 of the UBM layer 220 react slowly with tin atoms in the bumps 230, as the wetting-barrier layer 226 contains a nickel layer. Therefore, diffusion of the tin atoms in the bump 230 is lessened and the wetting effect between the UBM layer 220 and the bump 230 is maintained. As a result, the bonding (adhesion) strength between the bump 230 and the bonding pad 216 is increased, thus extending the life of the flip chip structure 200.

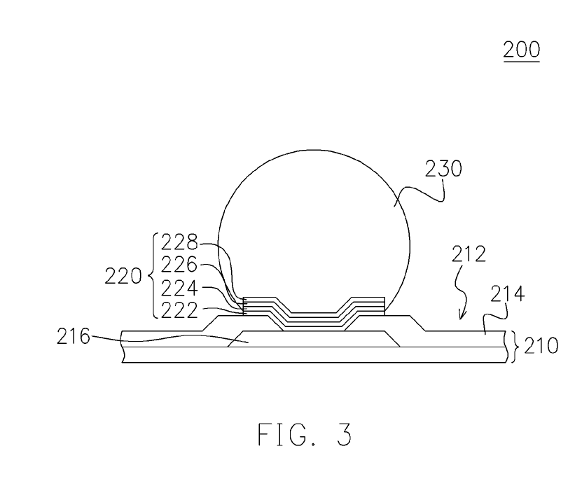

FIG. 3 is a cross-sectional view of a flip chip structure according to another preferred embodiment of the present invention. Referring to FIG. 3, the UBM layer 220 of the flip chip structure 200 further an anti-oxidation layer 228. The UBM layer includes the adhesion layer 222, the barrier layer 224, the wetting-barrier layer 226 and the anti-oxidation layer 228. The same reference numbers cited in FIG. 2 represent the same elements in FIG. 3 and will not be described here in details. The anti-oxidation layer 228 is disposed on the wetting-barrier layer 226. The material of the anti-oxidation layer 228 is gold (Au), for example. Because the anti-oxidation layer 228 isolates the wetting-barrier layer from the outer environments, no native oxide layer is formed on the wetting-barrier layer 226, before the UBM layer 220 is bonded to the bump 230. Therefore, no extra step is required for removing the native oxide layer, thus shortening the processing time for the formation of bumps.

In conclusion, the present invention has the following advantages: 1. As the wetting-barrier layer contains a nickel layer, nickel atoms in the wetting-barrier layer of the UBM layer react slowly with tin atoms in the bumps, thus slowing down the formation rate of the inter-metallic compounds. 2. Because the anti-oxidation layer protects the wetting-barrier layer, no native oxide layer is formed on the wetting-barrier layer. No extra step is required for removing the native oxide layer, thus shortening the processing time for the formation of bumps.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. An under bump metallurgy layer, between a bonding pad of a chip and a bump, for improving adhesion between the bonding pad and the bump, comprising:
an adhesion layer, disposed on the bonding pad;
a barrier layer, disposed on the adhesion layer; and
a wetting-barrier layer, disposed on the barrier layer and between the barrier layer and the bump, wherein a material of the bump comprises tin, and wherein a material of the wetting-barrier layer is made of nickel.

2. The under bump metallurgy layer of claim 1, wherein a material of the adhesion layer is selected from the following group consisting of titanium (Ti), titanium-tungsten (Ti-W) alloy, chromium (Cr), titanium nitride (TiN), tantalum nitride (TaN), tantalum (Ta), aluminum (Al) and copper (Cu).

3. The under bump metallurgy layer of claim 1, wherein a material of the adhesion layer is selected from the following group consisting of titanium, titanium-tungsten alloy, chromium, titanium nitride, tantalum nitride, tantalum and aluminum, if the bonding pad is made of aluminum.

4. The under bump metallurgy layer of claim 1, wherein a material of the adhesion layer is selected from the following group consisting of titanium, titanium-tungsten alloy, chromium, titanium nitride, tantalum nitride, tantalum and copper, if the bonding pad is made of copper.

5. The under bump metallurgy layer of claim 1, wherein a material of the barrier layer comprises nickel-vanadium alloy.

6. The under bump metallurgy layer of claim 1, wherein the under bump metallurgy layer further comprises an anti-oxidation layer and the anti-oxidation layer is disposed between the wetting-barrier layer and the bump.

7. The under bump metallurgy layer of claim 6, wherein a material of the anti-oxidation layer comprises gold.

8. A flip chip structure, comprising:
a chip having an active surface, a passivation layer and a plurality of bonding pads, wherein the bonding pads are disposed on the active surface and the passivation layer are disposed on the active surface exposing the bonding pads;
an under bump metallurgy layer, wherein the under bump metallurgy layer comprises:
an adhesion layer, disposed on the bonding pad;
a barrier layer, disposed on the adhesion layer; and
a wetting-barrier layer, disposed on the barrier layer, wherein a material of the wetting-barrier layer comprises nickel; and
a bump, disposed on the wetting-barrier layer.

9. The flip chip structure of claim 8, wherein a material of the adhesion layer is selected from the following group consisting of titanium (Ti), titanium-tungsten (Ti-W) alloy, chromium (Cr), titanium nitride (TiN), tantalum nitride (TaN), tantalum (Ta), aluminum (Al) and copper (Cu).

10. The flip chip structure of claim 8, wherein a material of the adhesion layer is selected from the following group consisting of titanium, titanium-tungsten alloy, chromium, titanium nitride, tantalum nitride, tantalum and aluminum, if the bonding pad is made of aluminum.

11. The flip chip structure of claim 8, wherein a material of the adhesion layer is selected from the following group consisting of titanium, titanium-tungsten alloy, chromium, titanium nitride, tantalum nitride, tantalum and copper, if the bonding pad is made of copper.

12. The flip chip structure of claim 8, wherein a material of the barrier layer comprises nickel-vanadium alloy.

13. The flip chip structure of claim 8, wherein the under bump metallurgy layer further comprises an anti-oxidation layer and the anti-oxidation layer is disposed between the wetting-barrier layer and the bump.

14. The flip chip structure of claim 13, wherein a material of the anti-oxidation layer comprises gold.

15. The flip chip structure of claim 8, wherein a material of the bump is made of tin-silver-copper alloy.

16. The flip chip structure of claim 8, wherein a material of the bump is made of tin-copper alloy.

17. The flip chip structure of claim 8, wherein a material of the bump comprises tin.

18. A flip chip structure, comprising:
a chip having an active surface, a passivation layer and a plurality of bonding pads, wherein the bonding pads are disposed on the active surface and the passivation layer are disposed on the active surface exposing the bonding pads;
an adhesion layer, disposed on the bonding pad;
a barrier layer, disposed on the adhesion layer; and
a wetting-barrier post, disposed on the barrier layer, wherein a thickness of the wetting-barrier post is larger than that of the adhesion layer; and
a bump, disposed on the wetting-barrier post.

19. The flip chip structure of claim 18, wherein a material of the wetting-barrier post is made of nickel.

20. The flip chip structure of claim 18, wherein a material of the bump is made of lead-free solder.

21. The flip chip structure of claim 18, wherein the thickness of the wetting-barrier post is larger than the thickness of the adhesion layer and the barrier layer.
